(19) United States
(12) Patent Application Publication
(10) Pub. No.: US 2025/0081519 A1
(43) Pub. Date: Mar. 6, 2025

(54) Trench Gate Semiconductor Device

(71) Applicant: Hangzhou Silicon-Magic Semiconductor Technology Co.,Ltd, Hangzhou (CN)

(72) Inventors: Leilei Chen, Hangzhou (CN); Jian Liu, Torrance, CA (US)

(73) Assignee: Hangzhou Silicon-Magic Semiconductor Technology Co.,Ltd, Hangzhou (CN)

(21) Appl. No.: 18/811,823

(22) Filed: Aug. 22, 2024

(30) Foreign Application Priority Data
Sep. 4, 2023 (CN) 202311135889X
Nov. 6, 2023 (CN) 2023114680160

(51) Int. Cl. H01L 29/78; H01L 29/06; H01L 29/40; H01L 29/417

(52) U.S. Cl. CPC H10D 30/668; H10D 30/665; H10D 62/127; H10D 64/117; H10D 64/252

(57) ABSTRACT

A semiconductor device having a ring-shaped cell region, a first termination region and a second termination region. The cell region includes a first base region, a source region in the first base region, first and second gate trench structures. The first base region and the source region are sandwiched by the first and second gate trench structure in a plane. The first termination region is surrounded by the ring-shaped cell region in the plane. The second termination region surrounds the ring-shaped cell region in the plane. The first termination region has a round-shaped source trench structure including a source electrode filling in a source trench with a source dielectric layer in between for insulation. The second termination region has a ring-shaped first source trench structure including a source electrode filling in a source trench with a source dielectric layer in between for insulation.

### CROSS-REFERENCE TO RELATED APPLICATION

This application claims the benefit of Chinese Patent Application No. 202311135889.X, filed on Sep. 4, 2023, and Chinese Patent Application No. 202311468016.0, filed on Nov. 6, 2023, which are incorporated herein by reference in its entirety.

### TECHNICAL FIELD

The present disclosure relates to semiconductor device structures and in particular to shield gate transistors with high cell density.

### BACKGROUND

SGT (Shield Gate Trench) MOSFET (Metal Oxide Semiconductor Field Effect Transistor) is a novel semiconductor device. Compared with the traditional trench MOSFET, the SGT MOSFET has a lower switching loss while keeping a low conductive loss. SGT MOSFETs, used as switches, are widely applied in motor driving systems, inverter systems and power management systems, like new energy vehicles, photovoltaic power devices and household appliances.

The main difference between the SGT MOSFETs and the traditional power devices is that deep trench structures are formed in the drift region of the SGT MOSFETs. The deep trench structures deplete the drift region between the trenches in a lateral direction, such that the drift region could have a higher doping concentration while still maintaining a high breakdown voltage. The higher doping concentration guarantees a low on-resistor for the SGT MOSFET.

With the development of the SGT MOSFET technology, separated gate trench and field plate trench structure provides more design flexibility. However, the SGT MOSFET with separated gate trench and field plate trench has large planar size, which obviously increases the cost.

### SUMMARY

In order to solve the technical problem in the prior art, the present application provides a shield gate trench MOSFET device and a method for manufacturing the same.

The embodiments of the present invention are directed to a semiconductor device including a ring-shaped cell region, a first termination region and a second termination region. The cell region includes a base region, a source region, a first gate trench structure and a second gate trench structure. The source region is in the base region, and has a smaller depth than the base region in a vertical direction normal to a surface of the semiconductor device. The base region and the source region are sandwiched by the first gate trench structure and second gate trench structure in a plane parallel to the surface of the semiconductor device. The first termination region is surrounded by the ring-shaped cell region in the plane parallel to the surface of the semiconductor device. The first termination region has a round-shaped source trench structure including a round-shaped source electrode filling in a round-shaped source trench with a source dielectric layer in between for insulation. The round-shaped source trench structure is in the middle of the first termination region. The second termination region surrounds the ring-shaped cell region in the plane parallel to the surface of the semiconductor device. The second termination region has a ring-shaped first source trench structure including a ring-shaped source electrode filling in a ring-shaped source trench with a source dielectric layer in between for insulation. Each one of the first gate trench structure and the second gate trench structure has a control gate electrode formed in an upper section of a gate trench with a gate electric layer in between for insulation, a first shield gate electrode formed in a lower section of the gate trench with the gate electric layer in between for insulation, and a second shield gate electrode formed in a portion of the gate trench. The second shield gate electrode adjoins the first shield gate electrode, and forms a ring with the first shield gate electrode. The control gate electrode is cut by the second shield gate electrode to have an opening, and is insulated from the first shield gate electrode and the second shield gate electrode by the gate dielectric layer.

The embodiments of the present invention are directed to a semiconductor device including a ring-shaped cell region, a first termination region and a second termination region. The cell region includes a first base region, a source region, a first gate trench structure and a second gate trench structure. The source region is in the first base region, and has a smaller depth than the first base region in a vertical direction normal to a surface of the semiconductor device. The first base region and the source region are sandwiched by the first gate trench structure and second gate trench structure in a plane parallel to the surface of the semiconductor device. The first termination region is surrounded by the cell region in the plane parallel to the surface of the semiconductor device. The first termination region has a round-shaped source trench structure including a source electrode filling in a source trench with a source dielectric layer in between for insulation. The second termination region surrounds the ring-shaped cell region in the plane parallel to the surface of the semiconductor device. The second termination region has a ring-shaped first source trench structure including a source electrode filling in a source trench with a source dielectric layer in between for insulation.

The embodiments of the present invention are directed to a semiconductor device including a ring-shaped cell region, a first termination region and a second termination region. The cell region includes a plurality of ring-shaped gate trench structures formed concentrically, a plurality of first base regions and a plurality of source regions. The plurality of source regions are in the plurality of first base regions respectively, and have a smaller depth than the plurality of first base regions in a vertical direction normal to a surface of the semiconductor device. Each one of the plurality of first base regions and associated one of the plurality of source regions are sandwiched by two neighboring gate trench structures in a plane parallel to the surface of the semiconductor device. The first termination region is surrounded by the cell region in the plane parallel to the surface of the semiconductor device. The first termination region has a round-shaped source trench structure including a source electrode filling in a source trench with a source dielectric layer in between for insulation. The second termination region surrounds the ring-shaped cell region in the plane parallel to the surface of the semiconductor device. The second termination region has a ring-shaped first source trench structure including a source electrode filling in a source trench with a source dielectric layer in between for insulation.

### BRIEF DESCRIPTION OF FIGURES

The present disclosure can be further understood with reference to following detailed description and appended drawings, wherein like elements are provided with like reference numerals. These drawings are only for illustration purpose, thus may only show part of the devices and are not necessarily drawn to scale. It is obvious that the drawings described below are some implementations of the present disclosure, and those skilled in the art would also obtain other drawings on the basis of these drawings, without involving any inventive skill.

FIG. 1a shows a plan view of a semiconductor device 100 in accordance with an embodiment of the present disclosure.

FIG. 1b shows the plan view of the semiconductor device 100 with each part of the plan view labeled in accordance with an embodiment of the present disclosure.

FIG. 1c shows a cross-sectional view of the semiconductor device 100 in FIG. 1b along lines A-O and B-O.

FIG. 1d shows a cross-sectional view of the semiconductor device 100 in FIG. 1b along line AC.

FIG. 1e shows a schematic perspective view of the semiconductor device 100 portion of FIG. 1a, in accordance with an embodiment of the present disclosure.

FIG. 2 shows a plan view of a semiconductor device 800 in accordance with an embodiment of the present disclosure.

The use of the same reference label in different drawings indicates the same or like components.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, well-known structures, materials, processes or operations are not shown or described in detail to avoid obscuring aspects of the present disclosure.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

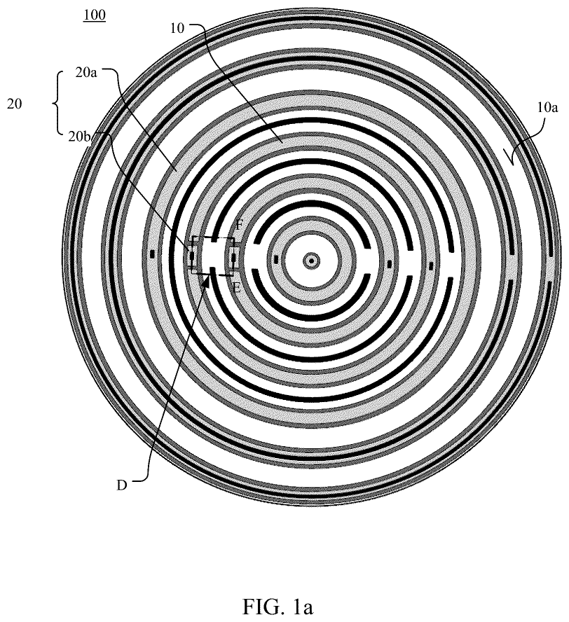

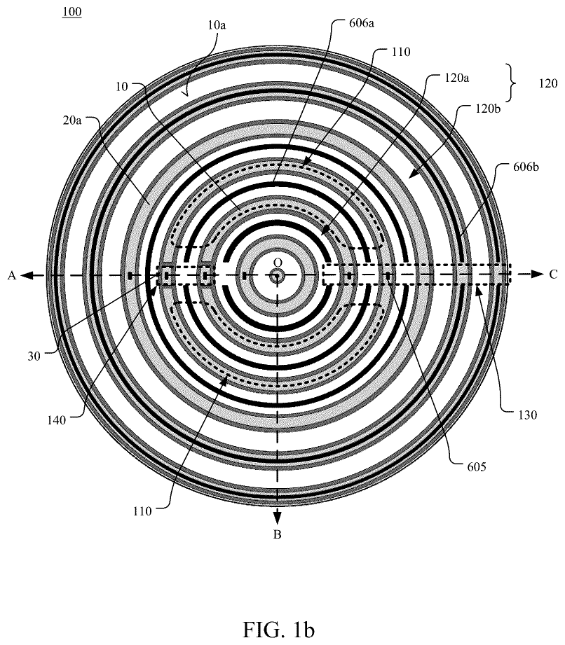

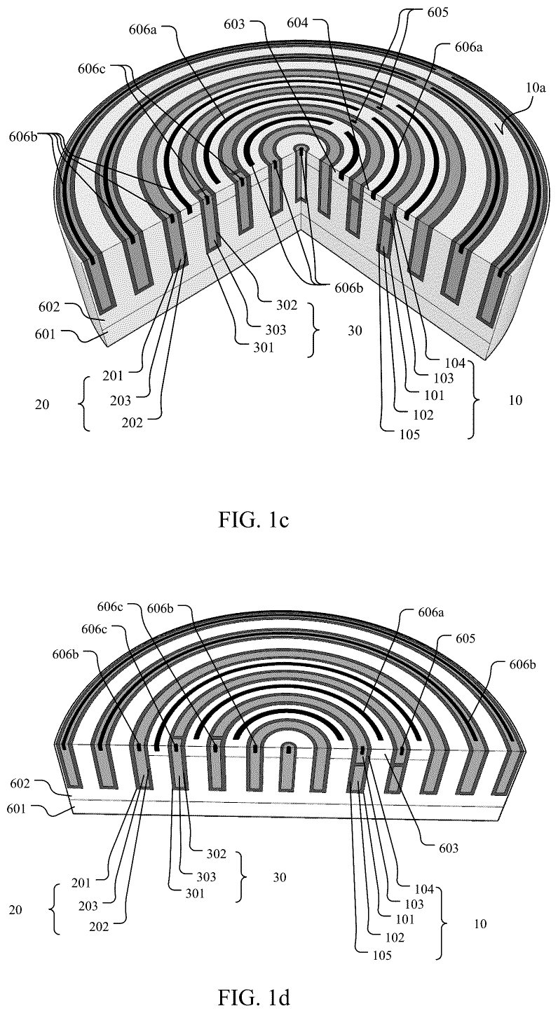

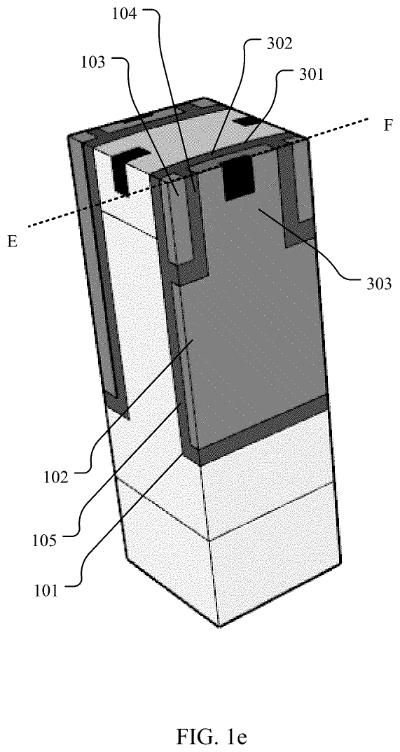

FIG. 1a shows a plan view of a semiconductor device 100 in accordance with an embodiment of the present disclosure. FIG. 1b shows the plan view of the semiconductor device 100 with each part of the plan view labeled in accordance with an embodiment of the present disclosure. FIG. 1c shows a cross-sectional view of the semiconductor device 100 in FIG. 1b along lines A-O and B-O. FIG. 1d shows a cross-sectional view of the semiconductor device 100 in FIG. 1b along line AC. FIG. 1e shows a schematic perspective view of the semiconductor device 100 portion of FIG. 1a, in accordance with an embodiment of the present disclosure. In the illustrated embodiments and for the following description, the first conductivity type is n-type and the second conductivity type is p-type. Similar considerations as outlined below apply to embodiments with the first conductivity type being p-type and the second conductivity type being n-type. By implanting n-type dopants, like P or As, into a semiconductor layer, n-type layer could be formed. By implanting p-type dopants, like B, into a semiconductor layer, p-type layer could be formed.

As could be seen from FIG. 1c to FIG. 1e, the semiconductor device 100 is based on a substrate 601 and an epitaxial layer 602 on the substate 601. The substrate 601 could be a single crystalline semiconductor material such as silicon (Si), strained silicon, germanium (Ge), silicon germanium crystal (SiGe), silicon carbide (SiC), gallium nitride (GaN), gallium arsenide (GaAs) or any other AmBy semiconductor. The substrate 601 is configured as part of a drain structure of the semiconductor device 100, and has the first conductivity type. In one embodiment, the substrate 601 is n-type with a high doping level, which means n-type dopants are implanted into the substrate 601 with high concentration. The epitaxial layer 602 could be formed by implanting dopants into the top portion of the substrate 601, or could be formed by an epitaxial growth process. According to one embodiment, a dopant concentration of the epitaxial layer 602 may be approximately uniform. According to other embodiments, the dopant concentration in the epitaxial layer 602 may gradually or in steps increase or decrease with increasing distance to the substrate 601 at least in portions of its vertical extension. The epitaxial layer 602 is configured as the drift region of the semiconductor device 100, and has the first conductivity type. In one embodiment, the epitaxial layer 602 is n-type, and has a lower doping level than the substrate 601.

FIGS. 1a and 1b show the first surface 10a of semiconductor device 100, which is also the first surface of the epitaxial layer 602. A normal to the first surface of the semiconductor 100 defines a vertical direction and directions orthogonal to the vertical direction are lateral directions.

As illustrated by FIG. 1b, the semiconductor device 100 provided by the present disclosure includes a cell region 110, a termination region 120, a control gate contact region 130 and a shield gate contact region 140.

The cell region 110 has gate trench structures 10. As shown in the embodiments of FIGS. 1c and 1d, the gate trench structure 10 includes a shield gate structure and a control gate structure. The gate trench structure 10 is formed in the cell region 110, and includes a gate trench 101, a first shield gate electrode 102 formed in a lower section of the gate trench 101, a control gate electrode 103 formed in an upper section of the gate trench 101. The gate trench 101 extends from the first surface 10a of the epitaxial layer 602 into the epitaxial layer 602. The control gate electrode 103 is above the first shield gate electrode 102 and is separated away from the first shield gate electrode 102 by an insulating layer. A gate dielectric layer 104 is formed between the control gate electrode 103 and the side walls of the gate trench 101 in the upper section. A first shield gate dielectric layer 105 is formed between the first shield gate electrode 102 and the lower section of the gate trench 101. The insulating layer between the control gate electrode 103 and the first shield gate electrode 102 connects with the gate dielectric layer 104 and the first shield gate dielectric layer 105, to insulate the first shield gate electrode 102 and the control gate electrode 103 from each other, and from the gate trench 101 as well.

The cell region 110 includes a base region 603 having a second doping type and a source region 604 having a first doping region as shown in the embodiment of FIGS. 1c and 1d. In the cell region 110, the base region 606 is formed in the epitaxial layer 602 between the neighboring gate trench structures 10. The base region 603 adjoins the neighboring gate trenches 101. The source region 604 is formed in the base region 603 between the neighboring gate trench structures 10 and adjoins the neighboring gate trenches 101. The horizontal cross-sectional area of the source regions 606, e.g., the source region 606 on the first surface of the semiconductor device 100 may be a circle, which makes the doping of the source region 604 controllable.

In the present disclosure, the gate trench structures 10 form rings on the plane parallel to the first surface 10a of the epitaxial layer 602. Adaptively, the base region 603 and the source region 604 are configured to have circle shapes on the plane parallel to the first surface 10a of the epitaxial layer 602. Accordingly, the cell region 110 is ring-shaped. The cell region 110 may have one or more than one gate trench structures, base regions and source regions according to application requirements.

First source contacts 606a are formed in the cell regions 110 in a ring shape. In the embodiments illustrated in FIGS. 1a and 1b, the first source contact 606a includes two semi-ring sections, leaving a path along a diameter of the ring of the first source contacts 606a. In other embodiments, the first source contact 606a could be broke into more sections, and leaving more than one paths along radiuses of the rings of the trench structures. The first source contacts 606a are arranged in the base region 603 and the source region 604. As can be seen from a cross-sectional view of the semiconductor device 100 shown in FIG. 1c, the source contact 606a is extending from the first surface of the semiconductor device 100, penetrating through the source region 604 to the base region 603. The first source contact 606a adjoins the source regions 604 and the base region 603. The two first source contacts 606a are accommodated to the base region 603 and the source region 604 to be an open ring from the horizontal cross-sectional view. The first source contacts 606a are sandwiched by the neighboring gate trench structures 10, and are separated from each other by the base region 603 and the source regions 604.

As shown FIG. 1c, the termination region 120 includes source trench structures 20. The source trench structure 20 includes a source trench 201, a source dielectric layer 202 and a source electrode 203. The source dielectric layer 202 is arranged between the source electrode 203 and the source trench 201, and separates the source electrode 203 from the sidewalls and bottom wall of the source trench 201. The source trench 201 extends vertically from the first surface 10a of the epitaxial layer 602, which is distanced from the substrate 601, into the epitaxial layer 602.

In the embodiments of FIG. 1b, the cell region 110 is ring-shaped, and has an opening in the middle. The termination regions 120 are arranged outside the outer contour of the ring-shaped cell region 110, and also inside the inner contour of the ring-shaped cell region 110. Accordingly, the termination region 120 includes a first termination region 120a in the inner region surrounded by the cell region 110 and a second termination region 120b outside the cell region 110. The first termination region 120a has a round shape at the plane parallel to the first surface 10a of the semiconductor device 100. The cell region 110 surrounds the first termination region 120a, and the second termination region 120b surrounds the cell region 110. The termination regions 120 include source trench structures 20. As illustrated in the embodiments of FIGS. 1a, 1b, 1c and 1d, the source trench structures 20 form a ring shape or a round shape (in the middle of the semiconductor 100) at the plane parallel to the first surface 10a of the semiconductor 100.

The termination region 120 includes second source contacts 606b. As illustrated in FIGS. 1c and 1d, the second source contacts 606b are embedded into and electrically connected to the source electrodes 203. The second source electrode 606b is adaptively ring-shaped at the plane parallel to the first surface 10a of the semiconductor device 100. In other embodiments, the second source electrode 606b could have other shapes at plane parallel to the first surface 10a of the semiconductor device 100, like square shape.

The termination region 120 may further include the base region 603. As shown in FIGS. 1c and 1d, the base regions 603 are formed in both the first termination region 120a and the second termination region 120b. The base region 603 is arranged between the neighboring source trench structures 20 (in the first termination region 120a), or between the neighboring source trench structure 20 in the termination region 120 and gate trench structure 10 in the cell region 110. The base region 603 is adapted to be a ring at the plane parallel to the first surface of the semiconductor 100. In one embodiment, the base region 603 in the termination region 120 and the base region 603 in the cell region 110 are formed at a same step, thus no additional processes are needed.

When the base region 603 is formed in the termination region 120, the second source electrode 606b are formed in the base region 603 in the termination region 120. The second source electrode 606b forms a ring with an opening as shown in FIG. 1b. The second source electrode 606b is isolated from the source trench structure and the gate trench structure 10 by the base region 603.

The control gate contact region 130 is configured for connecting the control gate contact 605 to metals or other conductive layer which are electrically connected to the gate power of the semiconductor device 100, i.e., the control gate contacts 605 are arranged in the control gate contact region 130. In order to connect the control gate electrodes 103 to the gate power, the gate trench structure 10 is extended across the control gate contact region 130, i.e., the gate trench structure 10 is arranged in both the cell region 110 and the control gate contact region 130.

As shown in FIGS. 1b-1d, the control gate contacts 605 are embedded in the gate trench structure 10 in the control gate contact region 130. The control gate contact 605 electrically contacts the control gate electrode 103. In some embodiments of the present disclosure, multiple gate trench structures 10 are configured in the cell region 110. Each gate trench structure 10 has a control gate contact 605. The multiple gate trench structures 10 are electrically paralleled, such that the gate resistance of the semiconductor device 100 is reduced.

In order to connect the control gate contacts 605 to a same gate power, the control gate contacts 605 in different gate trench structures 10 are lined up. Correspondingly, the control gate contact region 130 has a stripe shape. In one embodiment, the control gate contact region 130 is distributed in a semidiameter of the semiconductor device 100, with one end in the first termination region 120a, and the other end of the control gate contact region 130 reaching an outermost edge of the second termination region 120b. The control gate contact region 130 makes openings to the source contacts 606a and 606b.

As shown in FIG. 1b, the control gate contact region 130 crosses the gate trench structures 10 and the source trench structures 20. For avoiding short circuit of the control gate contacts 605 to the first source contacts 606a and the second source contacts 606b, the ring-shaped first source contacts 606a and second source contacts 606b have openings in the control gate contact region 130, i.e., the control gate contact region 130 is devoid of the first source contacts 606a and the second source contacts 606b. Meanwhile, the control gate contact region 130 is also devoid of the source region 604.

It should be understood that the control gate contacts 605 may be arranged in other patterns, and the control gate contact region 130 accommodating the control gate contacts 605 may have different shapes correspondingly.

Shield gate trench structures 30 and shield gate contacts 606c embedded in the shield gate trench structures 30 are configured in a shield gate contact region 140. The first shield gate electrode 102 are electrically coupled to a desired power through the shield gate contacts 606c.

In order to connect the first shield gate electrode 102 to a desired power, the control gate electrodes 103 and the control gate contacts 605 are devoid in the shield gate contact region 140, i.e., the ring-shaped control gate electrodes 103 have openings in the shield gate contact region 140 as shown in FIG. 1b. The first shield gate contact electrode 120 forms a ring under the respective control gate electrode 103, and extends vertically up to the first surface 10a of the semiconductor device 100 in the shield gate contact region 140. As shown in the embodiment of FIG. 1c, the shield gate trench structure 30 includes a shield gate trench 301, a second shield gate electrode 303 and a second shield gate dielectric layer 302. The second shield gate dielectric layer 302 covers an inner surface of the shield gate trench 301, and insulates the second shield gate electrode 303 from the shield gate trench 301. The shield gate trench 301 extends vertically from the first surface 10a of the semiconductor device 100 into the epitaxial layer 602. The shield gate trench 301 adjoins the gate trench 101 to form a ring. The second shield gate electrode 303 adjoins the first shield gate electrode 102 to form a ring. The second shield gate electrode 303 in the shield gate trench 301 is insulated from the control gate electrode 103 through the gate dielectric layer 104. The shield gate contacts 606c is embedded into the second shield gate electrode 303, and electrically connects the second shield gate electrode 303 in the shield gate contact region 140.

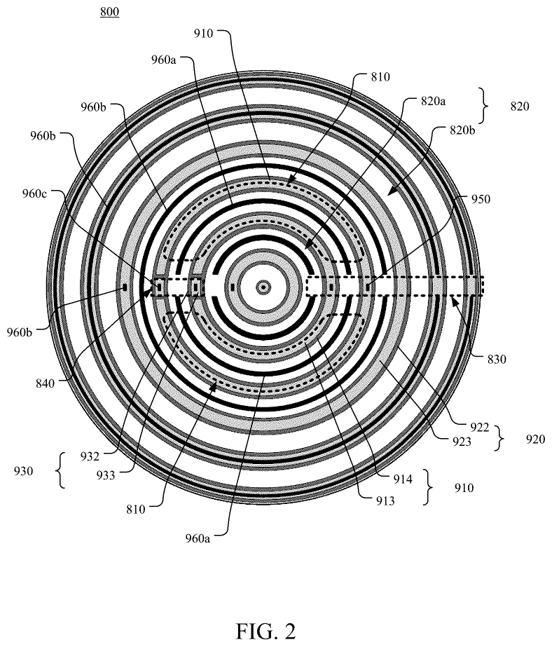

In the embodiments of the present disclosure, each control gate electrode 103 has an opening in the shield gate contact region 140, i.e., each control gate electrode 103 is devoid in the shield gate contact region 140. The openings are lined up in the shield gate contact region 140. The devoid regions of the control gate electrodes 103 leave space for the shield gate contacts 606c to contact the second shield gate electrode 303. Consequently, the shield gate contacts 606c are arranged in a stripe and the shield gate contact region 140 accommodating the shield gate contacts 606c is in a stripe-shape. The stripe-shaped shield gate contacts 606c and together with the stripe-shaped gate contact region 130 separate the ring-shaped cell region 110 into two half-ring regions as shown in FIGS. 1b and 2. It should be understood that the shield gate structure 30 may be arranged in other patterns, and the shield gate contact region 140 accommodating the shield gate structures 30 may have different shapes correspondingly.

In the embodiments of FIGS. 1a-1e, one control gate contact region 130 and one shield gate contact region 140 are configured in the semiconductor device 100. In other embodiments, more than one control gate contact regions 130 and more than one shield gate contact regions 140 may be configured in the semiconductor device 100. The control gate contact regions 130 and the shield gate contact regions 140 in some embodiments may be arranged in any openings of the cell region 110, and may cut the ring-shaped control gate electrodes 103, the ring-shaped source contacts 606a and 606b, and ring-shaped source region 606 into arcs.

The first source contact 606a in the cell region 110 is at least cut by control gate contact region 130 to leave an opening in the control gate contact region 130, i.e., the first source contact 606a is devoid in the control gate contact region 130. In the embodiments of FIGS. 1a-1e, the ring-shaped first source contact 606a is cut into two half-rings by the control gate contact region 130 and the shield gate contact region 140, such that the first source contact 606a is insulated from the control gate contact 605. In some embodiments, the first source contact 606a may be distributed in the shield gate contact region 140, while having an opening in the control gate contact region 130. In further embodiments, the first source contact 606 may have multiple openings as required.

The second source contact 606b in the termination region 120 is at least cut by the control gate contact region 130, and is devoid in the control gate contact region 130. In the embodiments of FIGS. 1a-1e, the ring-shaped second source contact 606b is opened by the control gate contact region 130. In some embodiments, the second source contact 606a may have multiple openings and may have the opening in any section of the termination region 120.

It should be understood that the semiconductor device 100 is divided into the cell regions 110, the termination region 120, the control gate contact region 130 and the shield gate contact region 140 for illustration. In the real semiconductor device, the regions are not separated. The doted lines in FIGS. 1a, 1b and 2 are labeled for illustration purposes, and are not exited in a real semiconductor device.

The gate dielectric layer 104, the first shield gate dielectric layer 105, the source dielectric layer 202, the second shield gate dielectric layer 302 and other dielectric layers in the embodiments of the present disclosure may include or may consist of a semiconductor oxide, or a material having a dielectric constant greater than SiO₂, including, for example, oxides, nitrides, nitrogen oxides, silicates, aluminates, titanates. Moreover, the gate dielectric layer 104, the first shield gate dielectric layer 105, the source dielectric layer 202, the second shield gate dielectric layer 302 and other dielectric layers may include not only from materials known to those skilled in the art, but also from materials developed in the future for use of insulation. The first shield gate electrode 102, the control gate electrode 103, the first source electrode 203a, the second shield gate electrode 303 may consist of or include conductive materials like metal, polysilicon, or two or more sub-layers, wherein each sub-layer contains one or more of Ni, Sn, Ti, V, Ag, Au, Pt, W, and Pd as main constituent(s).

The semiconductor device 100 may include other dielectric layers, gate metal layers, source metal layers and drain metal layers which are not shown in the FIGs of the present disclosure. The dielectric layers may cover the surface of the epitaxial layer 602, the gate trench structures 10, the source trench structures 20 and the shield gate structures 30 for insulation.

The gate metal layer covers the surface of the semiconductor device 100 which is distanced from the substrate 601 with the dielectric layers in between for insulation. The gate metal layer connects to the control gate electrode 103 in the cell region 110 via the control gate contacts 605. In some embodiments, the control gate electrodes 103 configured in the same ring-shaped gate trench structure 10 are connected to the same gate metal layer via the control gate contacts 605.

The source metal layer covers the surface of the semiconductor device 100 which is distanced from the substrate 601 with the dielectric layers in between for insulation. The source metal layers connect to the first source contacts 606a, the second source contacts 606b and the shield gate contacts 606c through vias or other conductive structures. Specifically, the source metal layers connect to the source region 604 and the base regions 603 in the cell regions 110 via the first source contacts 606a, connect to the first source electrodes 203 and base region 603 in the termination region 120 via the second source contacts 606b, and connect to the first shield gate electrode 102 in the cell region 110 via the shield gate contacts 606c. The source metal layer and the gate metal layer are separated and insulated from each other.

The substrate 601 has a first surface contacting the epitaxial layer 602 and a second surface opposite to the first surface. The drain metal layer is arranged on the second surface of the substrate 601, and is electrically connected to the substrate 601.

FIG. 2 shows a plan view of a semiconductor device 800 in accordance with an embodiment of the present disclosure. As shown in FIG. 2, the semiconductor device 800 includes a cell region 810, termination regions 820, a control gate contact region 830 and a shield gate contact region 840. The cell region 810 is in a ring-shape. The termination region 820 includes a first termination region 820a surrounded by cell region 810, and a second termination region 820b surrounding the cell region 810. The first termination region 820a has a round shape at a plane parallel to a first surface 80a of the semiconductor device 800. The cell region 810 surrounds the first termination region 820a, and the second termination region 820b surrounds the cell region 810.

The control gate contact region 830 has a stripe shape. The stripe-shaped control gate contact region 830 makes openings to the source contacts 960a and 960b. In one embodiment, the control gate contact region 830 is distributed in a semidiameter of the semiconductor device 800, with one end in the first termination region 820a, and the other end of the control gate contact region 830 reaching an outermost edge of the second termination region 820b. The shield gate contact region 840 has a stripe shape, which makes openings to the source contact 960a and the control gate electrodes 950. In one embodiment, the shield gate contact region 840 has an end in the first termination region 820a and the other end reaching the second termination region 820b. The control gate contact regions 830 and the shield gate contact regions 840 in some embodiments may be arranged in any openings of the cell region 810, and may cut the ring-shaped control gate electrode 950 and ring-shaped source electrode 960a into arcs.

The semiconductor device 800 includes gate trench structures 910 and the source trench structures 920. The source trench structures 920 includes the source electrode 923 and the source dielectric layer 922.

The gate trench structures 910 are configured in the cell region 810. The gate trench structures 910 form rings and cross the control gate contact region 830. The ring-shaped gate trench structures 910 are cut by the shield gate contact region 840 and have openings in the shield gate contact region 840. The gate trench structure 910 includes the gate dielectric layer 914 covering the inner surface of the gate trench and a control gate electrode 913 filling in the gate trench structure 910.

The source trench structures 920 are configured in the terminal region 820, i.e., both the first termination region 820a and the second termination region 820b. The source trench structures 920 cross the control gate contact region 830 and form rings in the termination region 820. In the center point area of the semiconductor device 800, the source trench structure 920 is round with a source contact at the center point as shown in FIG. 2. Each source trench structures 920 includes the source dielectric layer 922 covering the inner side of the source trench and the source electrode 923 filling in the source trench.

The shield gate trench structure 930 is configured in the shield gate contact region 840. The shield gate trench structure 930 is in the openings of the gate trench structures 910, and form a ring together with the control gate trench 910. The shield gate trench structure 930 includes a second shield gate dielectric layer 932 and a second shield gate electrode 933. The second shield gate electrode 933 is insulated from the control gate electrode 913 by the second shield gate dielectric layer 932. The second shield gate dielectric layer 932 together with the gate dielectric layer 914 surrounds the second shield gate electrode 933 and the control gate electrode 913.

The semiconductor device 800 includes the control gate contacts 950 and source contacts 960.

The control gate contacts 950 are embedded in the gate trench structures 910 in the control gate contact region 830. In the control gate contact region 830, the control gate contact 950 is in the control gate electrode 913 of the gate trench structure 910. When more than one gate trench structures 910 are configured in the cell region 810, each gate trench structure 910 includes at least one control gate contact 950.

The source contacts 960 includes the first source contacts 960a in the cell region 810, the second source contacts 960b in the termination region 820, and the shield gate contacts 960c in the shield gate contact region 840.

In the cell region 810, the first source contacts 960a is configured between the neighboring gate trench structures 910. The first source contact 960a is adaptively formed in a ring shape. The first source contacts 960a are sandwiched by and insulated from the gate trench structures 910 in the plane parallel to the first surface 10a of the semiconductor device 800. Each ring-shaped first source contact 960a is opened by the control gate contact region 830 and the shield gate contact region 840, and is cut into arcs in some embodiments. The first source contact 906a is insulated from the control gate electrodes 950.

In the termination region 120, some of the second source contacts 960b are embedded into the source electrode 923 of the source trench structures 920. The second source contact 960b is adapted to the source trench structure 920 to be a ring shape. The ring-shaped second source contact 960b is opened by the control gate contact region 830. The second source contact 960b is insulated from the control gate contact 950.

Moreover, in the termination region 820, some of the second source contacts 960b configured between the neighboring gate trench structure 910 and the source gate trench structure 920 have ring-shapes adaptively, and are insulated from the neighboring gate trench structure 910 and the source gate trench structure 920. The ring-shaped second source contacts 960a are opened by the control gate contact region 830.

The shield gate contacts 960c are configured in the shield gate contact region 840, and are embedded in the shield gate trench structures 930. The shield gate contacts 960c are insulated from the control gate contacts 950.

While various embodiments have been described above to illustrate the semiconductor device and its manufacturing method of the present disclosure, it should be understood that they have been presented by way of example only, and not limitation. Rather, the scope of the present disclosure is defined by the following claims and includes combinations and sub-combinations of the various features described above, as well as variations and modifications thereof, which would occur to persons skilled in the art upon reading the foregoing description.

1. A semiconductor device, comprising:
a ring-shaped cell region, wherein the cell region includes a base region, a source region, a first gate trench structure and a second gate trench structure, and wherein the source region is in the base region, and has a smaller depth than the base region in a vertical direction normal to a surface of the semiconductor device, and wherein the base region and the source region are sandwiched by the first gate trench structure and second gate trench structure in a plane parallel to the surface of the semiconductor device;
a first termination region, surrounded by the ring-shaped cell region in the plane parallel to the surface of the semiconductor device, wherein the first termination region has a round-shaped source trench structure including a round-shaped source electrode filling in a round-shaped source trench with a source dielectric layer in between for insulation, and wherein the round-shaped source trench structure is in the middle of the first termination region; and
a second termination region, surrounding the ring-shaped cell region in the plane parallel to the surface of the semiconductor device, wherein the second termination region has a ring-shaped first source trench structure including a ring-shaped source electrode filling in a ring-shaped source trench with a source dielectric layer in between for insulation;
wherein each one of the first gate trench structure and the second gate trench structure has a control gate electrode formed in an upper section of a gate trench with a gate electric layer in between for insulation, a first shield gate electrode formed in a lower section of the gate trench with the gate electric layer in between for insulation, and a second shield gate electrode formed in a portion of the gate trench, wherein the second shield gate electrode adjoins the first shield gate electrode, and forms a ring with the first shield gate electrode, and wherein the control gate electrode is cut by the second shield gate electrode to have an opening, and is insulated from the first shield gate electrode and the second shield gate electrode by the gate dielectric layer.

2. The semiconductor device of claim 1, further comprising:
control gate contacts, configured in the first gate trench structure and the second gate trench structure for electrically connecting the control gate electrodes in the first gate trench structure and the second gate trench structure, wherein the control gate contacts are lined up; and
a control gate contact region, configured for accommodating the control gate contacts, and is formed in a stripe shape, wherein the control gate contact region makes openings to the source region and the base region.

3. The semiconductor device of claim 1, further comprises:
source contacts, configured in the round-shaped source trench structure, the ring-shaped first source trench structure and the source region, wherein the source contacts are electrically connected.

4. A semiconductor device, comprising:
a ring-shaped cell region, wherein the cell region includes a first base region, a source region, a first gate trench structure and a second gate trench structure, and wherein the source region is in the first base region, and has a smaller depth than the first base region in a vertical direction normal to a surface of the semiconductor device, and wherein the first base region and the source region are sandwiched by the first gate trench structure and second gate trench structure in a plane parallel to the surface of the semiconductor device;
a first termination region, surrounded by the cell region in the plane parallel to the surface of the semiconductor device, wherein the first termination region has a round-shaped source trench structure including a source electrode filling in a source trench with a source dielectric layer in between for insulation; and
a second termination region, surrounding the ring-shaped cell region in the plane parallel to the surface of the semiconductor device, wherein the second termination region has a ring-shaped first source trench structure including a source electrode filling in a source trench with a source dielectric layer in between for insulation.

5. The semiconductor device of claim 4, wherein the first termination region comprises:
a ring-shaped second source trench structure, having a source electrode filling in a source trench with a source dielectric layer in between for insulation, wherein the ring-shaped second source trench structure surrounds the round-shaped source trench structure.

6. The semiconductor device of claim 5, wherein the first termination region further comprises:
a second base region, arranged between the round-shaped source trench structure and the ring-shaped second source trench structure, the second base region adjoins the round-shaped source trench structure and the ring-shaped second source trench structure.

7. The semiconductor device of claim 5, wherein the first termination region further comprises:
a third base region, arranged between the ring-shaped second source trench structure and the first gate trench structure, wherein the third base region adjoins the ring-shaped second source trench structure and the first gate trench structure.

8. The semiconductor device of claim 7, wherein the first termination region further comprises:
source contacts, configured in the round-shaped source trench structure, the ring-shaped second source trench structure and the third base region, wherein the source contacts electrically connect the source electrode in the round-shaped source trench structure, the source electrode in the ring-shaped second source trench structure and the third base region.

9. The semiconductor device of claim 4, wherein the second termination region further comprises:
a ring-shaped third source trench structure, having a source electrode filling in a source trench with a source dielectric layer in between for insulation.

10. The semiconductor device of claim 9, wherein the second termination region further comprises:
source contacts, configured in the ring-shaped first source trench structure and the ring-shaped third source trench structure, wherein the source contacts electrically connect the source electrode in the ring-shaped first source trench structure and the source electrode in the ring-shaped third source trench structure.

11. The semiconductor device of claim 4, wherein the second termination region further comprises:
a fourth base region, arranged between the second gate trench structure and the ring-shaped first source trench structure, wherein the fourth base region adjoins the second gate trench structure and the ring-shaped first source trench structure.

12. The semiconductor device of claim 4, wherein the cell region further comprises:
a source contact, configured in the source region and the first base region, wherein the source contact electrically connects the source region and the first base region.

13. The semiconductor device of claim 4, wherein each one of the first gate trench structure and the second gate trench structure comprises:
a control gate electrode, formed in an upper section of a gate trench with a gate electric layer in between for insulation;
a first shield gate electrode, formed in a lower section of the gate trench with the gate electric layer in between for insulation, wherein the first shield gate electrode is insulated from the control gate electrode by the gate dielectric layer; and
a second shield gate electrode, formed in a portion of the gate trench, wherein the second shield gate electrode adjoins the first shield gate electrode, and forms a ring with the first shield gate electrode, and wherein the control gate electrode is cut by the second shield gate electrode to have an opening, and is insulated from the second shield gate electrode by the gate dielectric layer.

14. The semiconductor device of claim 13, wherein the second shield gate electrode is electrically connected to the source region and the first base region.

15. The semiconductor device of claim 13, further comprising:
control gate contacts, configured in the first gate trench structure and the second gate trench structure for electrically connecting the control gate electrodes in the first gate trench structure and the second gate trench structure; and
a control gate contact region, configured for accommodating the control gate contacts.

16. A semiconductor device, comprising:
a ring-shaped cell region, wherein the cell region includes a plurality of ring-shaped gate trench structures formed concentrically, a plurality of first base regions and a plurality of source regions, and wherein the plurality of source regions are in the plurality of first base regions respectively, and have a smaller depth than the plurality of first base regions in a vertical direction normal to a surface of the semiconductor device, and wherein each one of the plurality of first base regions and associated one of the plurality of source regions are sandwiched by two neighboring gate trench structures in a plane parallel to the surface of the semiconductor device;
a first termination region, surrounded by the cell region in the plane parallel to the surface of the semiconductor device, wherein the first termination region has a round-shaped source trench structure including a source electrode filling in a source trench with a source dielectric layer in between for insulation; and
a second termination region, surrounding the ring-shaped cell region in the plane parallel to the surface of the semiconductor device, wherein the second termination region has a ring-shaped first source trench structure including a source electrode filling in a source trench with a source dielectric layer in between for insulation.

17. The semiconductor device of claim 16, further comprising:
source contacts, configured in the round-shaped source trench structure, the ring-shaped first source trench structure and the plurality of source regions, wherein the source contacts are electrically connected.

18. The semiconductor device of claim 16, wherein each one of the plurality of gate trench structures comprises:
a control gate electrode, formed in an upper section of a gate trench with a gate electric layer in between for insulation;
a first shield gate electrode, formed in a lower section of the gate trench with the gate electric layer in between for insulation, wherein the first shield gate electrode is insulated from the control gate electrode by the gate dielectric layer; and
a second shield gate electrode, formed in a portion of the gate trench, wherein the second shield gate electrode adjoins the first shield gate electrode, and forms a ring with the first shield gate electrode, and wherein the control gate electrode is cut by the second shield gate electrode to have an opening, and is insulated from the second shield gate electrode by the gate dielectric layer.

19. The semiconductor device of claim 18, wherein the second shield gate electrode is electrically connected to the source region and the first base region.

20. The semiconductor device of claim 18, further comprising:
a plurality of control gate contacts, configured in the plurality of gate trench structures respectively for electrically connecting the control gate electrodes in the plurality of gate trench structures; and
a control gate contact region, configured for accommodating the control gate contacts.
